(19) United States
(12) Patent Application Publication
(10) Pub. No.: US 2025/0169011 A1
(43) Pub. Date: May 22, 2025

(54) FIELD DEVICE ASSEMBLY FOR PROCESS AND AUTOMATION TECHNOLOGY

(71) Applicant: WIKA Alexander Wiegand SE & Co. KG, Klingenberg/Main (DE)

(72) Inventors: Philipp MEDWED, Amorbach (DE); Alexander KOCH, Goldbach (DE); Peter BRETZ, Buergstadt (DE)

(73) Assignee: WIKA Alexander Wiegand SE & Co. KG, Klingenberg/Main (DE)

(21) Appl. No.: 18/955,370

(22) Filed: Nov. 21, 2024

(30) Foreign Application Priority Data
Nov. 21, 2023 (DE) 10 2023 132 385.7

(51) Int. Cl. H05K 5/02; H01R 35/02; H05K 5/06

(52) U.S. Cl. CPC H05K 5/0247; H05K 5/062; H01R 35/02

(57) ABSTRACT

A field device assembly for process and automation technology, including a housing and at least one first chamber and one second chamber arranged in the housing. At least one first module is arranged in the first chamber and at least one second module is arranged in the second chamber. The two chambers (are connected via at least one passage. The field device assembly also includes an electrical connecting element that is guided in at least one passage, the electrical connecting element being provided to establish an electrical connection between the first module and the second module. The electrical connecting element is made up, at least in part, of rigid sections and flexible sections and is provided with contact surfaces or contact elements for contacting the modules.

This nonprovisional application claims priority under 35 U.S.C. § 119 (a) to German Patent Application No. 10 2023 132 385.7, which was filed in Germany on Nov. 21, 2023, and which is herein incorporated by reference.

### BACKGROUND OF THE INVENTION

### Field of the Invention

The invention relates to a field device assembly.

### Description of the Background Art

Field devices with cast housings having at least one chamber are known from the prior art. FIGS. 1a through 1c show an opened field device housing from Rosemount from the year 2010. Two pin contacts cast with a casting compound establish electrical contacting between two separate chambers of the housing.

Furthermore, DE 102021132304 A1 discloses a field device having two chambers that are separated from one another by a partition wall. The partition wall has a bored passage whose walls have a surface that is structured in part. For example, a thread is proposed for the structured surface. A conductor element is at least partially inserted into the passage borehole for the electronic connection of two units. The passage borehole is also cast with a casting compound.

A drawback of the prior art is the considerable post-processing effort for the housing leadthroughs or chamber leadthroughs, and the limited number of electrical connections.

### SUMMARY OF THE INVENTION

It is therefore an object of the invention to provide an improvement for a chamber leadthrough which meets the requirements for use in explosion hazard areas.

In an example, a field device assembly for process and automation technology can include a housing, at least one first chamber and one second chamber arranged in the housing, at least one first module being arranged in the first chamber and at least one second module being arranged in the second chamber, wherein the two chambers are connected via at least one passage. In addition, the field device assembly includes an electrical connecting element that is guided in at least one passage, the electrical connecting element being provided to establish an electrical connection between the first module and the second module. The electrical connecting element is made up, at least in part, of rigid sections and flexible sections, and is provided with contact surfaces or contact elements for contacting the modules.

The electrical connecting element may be a rigid-flex circuit board, for example. The contact elements may be pins, plug, sockets, or the like, for example. Use of a rigid-flex circuit board allows versatile use of the electrical connecting element and also simplifies installation thereof.

At least one of the modules may be a terminal block, for example, for connecting electrical lines, such as a 4-20 mA loop or a bus system. In addition, one of the modules may also be an evaluation unit for evaluating and processing measured values and data. Both modules may be installed in either of the two chambers and exchanged with one another as desired. The housing is thus particularly versatile and flexible in its application.

The housing can have a third chamber in which a sensor module is arranged. The sensor module may include a pressure, temperature, or filling level sensor, for example. Such a multichamber housing has the advantage that multiple units/modules or sensors may be arranged separately from one another in different chambers. The chambers themselves thus remain as small as possible, and oxygen-containing air present therein, which under unfavorable conditions can ignite, may be reduced to a minimum.

The housing can have at least two passages: a first passage connecting the first chamber to the second chamber, and a second passage connecting the first chamber to the third chamber. Furthermore, it may also be conceivable for the second chamber to be connected to the third chamber via a passage. In particular for the requirements of ignition protection class Ex d, the example with two passages is advantageous, since in contrast to one passage, large open spaces are avoided. The advantage just mentioned is increased when a cross section of the passages is selected to be as small as possible.

The electrical connecting element can establish an electrical connection between the first module and the second module and also between the first module and the sensor module. The electrical connecting element has a multipole design, for example, for the simultaneous and independent supplying of power and data and/or signal transmission. The electrical connecting element is guided in the at least one passage, in particular in such a way that the inner walls of the passage are not contacted. Auxiliary elements, for example small spacers made of plastic or fine fibers or a plastic spring or plastic coil, may be provided for this purpose.

The first chamber and the second chamber can be angled relative to one another. The angle of the chambers relative to one another may be in a range of 5 to 90 degrees, in particular between 15 and 30 degrees, for example. The housing around the respective chambers may likewise have the mentioned angular range. Due to the angled arrangement of the chambers, a passage in angled form may also result. The readability of displays or status lights in the chambers is improved by an angled housing.

At least one passage can be cast with a casting material. The casting material may be epoxy resin or the like, for example. Sealing of the passage or passages is achieved by the casting. In addition, the requirements for ignition protection classes Ex d and Ex i may be met in this way.

The rigid sections of the electrical connecting element can be arranged in a receptacle in an entry area of the passage and at least partially cover the passage. At least one rigid section is, for example, arranged in the entry area in such a way that the rigid section is in flush alignment with an inner wall of the particular chamber.

A sealing element can be arranged in the entry area of the passage. The sealing element together with the shape of the entry area and the rigid section of the electrical connecting element achieves an additional increased sealing effect.

At least one rigid section of the electrical connecting element can be pressed into an entry area or a sealing element of the passage supported there and seals off the passage, and on the oppositely arranged opening in the passage is at least partially covered by a further rigid section of the electrical connecting element. The casting compound may be filled particularly easily into the passage from the opening in the passage, which is only partially covered. In comparison, the completely sealed opening prevents the casting from uncontrollably passing through or flowing out. A plug or a socket can be arranged at the rigid section and only partially covers the opening in the passage, so that the casting compound may also be cast across the rigid section. The plug or the socket thus remains contactable. Contact surfaces arranged on the rigid section may thus be easily insulated.

The at least one passage can have at least one undercut. A creepage distance may thus be effectively extended. At least two undercuts may be symmetrically arranged in each passage, thus maintaining the same distance from the respective rigid sections supported at the openings in the passage. This design is particularly advantageous for large temperature fluctuations, since the undercuts may prevent the casting from coming loose in the passage.

Use of the cast parts and housing parts without post-processing is particularly advantageous, since due to the cooperation of the undercut with the cast part surface and roughness of the surface, an optimal combination of the sealing effect and adhesion with regard to compressive strength and seal-tightness is achieved.

The rigid sections of the electrical connecting element can be made up of multiple layers, and at least at a surface facing the modules have contact surfaces and/or plug connectors that establish the electrical connection to the modules. Due to the arrangement of plug connectors, it is possible, for example, to cast the rigid section with the casting compound and thus insulate it, while still maintaining the electrical contactability. By use of a multilayer circuit board, a plurality of lines may be guided on a small space while electrically separating the lines from one another.

The rigid sections of the electrical connecting element can have electrical and/or electronic components. The components may be resistors, capacitors, transistors, and microcontrollers, for example, which in part may be arranged at an uppermost layer of the electrical connecting element or interior layers. Use is made of available open space in the passage by integrating electrical and/or electronic components into the electrical connecting element.

The flexible sections of the electrical connecting element can be arranged in the at least one passage. Particularly simple installation with regard to an angled housing with angled chambers is thus achieved. In this regard, it may be particularly advantageous for the flexible section to have an overlength compared to the length of the passage. Particularly simple installation is thus likewise possible.

The first module and/or the second module can be designed in such a way that a display module is attachable. One of the two modules may be designed in such a way that a display module is easily attachable and lockable, using a bayonet lock, for example. In addition, both modules may have an identical connector block or terminal block, so that the display module may be arranged in both chambers. For an angled housing, different angles result in which a display on the display module may be read.

The housing ican bes manufactured from sheet metal in the casting, die casting, or hydroforming process in which the inner walls of the passage are also unmachined. A housing that is manufactured in the hydroforming process is particularly suited for use in the food and beverage industry. In contrast, a housing made of cast iron, for example gray cast iron, is particularly robust and can withstand high pressures. The inner surfaces of the passage of a cast housing do not have to be post-processed for casting with a casting compound, since a cast housing already has a certain roughness to which the casting material can adhere, and typically passes through various cleaning processes after manufacture to remove release agents or minor burrs, for example. In addition to rinsing processes, these include machining by vibratory finishing or sandblasting.

The electrical connecting element can be cast in a block that is centrally supported in the housing. This example is particularly advantageous with regard to housings that are manufactured in the hydroforming process. Particularly good, simple sealing of the chambers may be achieved in this way. The block may, for example, also be prefabricated outside the housing and affixed in the housing, for example glued in, as an assembly unit.

The modules can be fixed and/or oriented to the block. The modules may be screwed to or plugged into the block, for example. In addition, a display module may be installed in the chambers. Due to an angled housing and a correspondingly angled block, the display module is alignable in the chamber in such a way that the display of the display module is easily readable.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a to 1c show a prior art field device housing with a cast chamber leadthrough from Rosemount,

FIG. 2 shows an example of a field device assembly,

FIG. 3 schematically shows an electrical connecting element,

FIG. 4 shows an example of a field device assembly,

FIG. 5 shows an example of a field device assembly,

FIG. 6 shows an example of an electrical connecting element, and

FIG. 7 shows an example of a field device assembly with a cloud connection.

### DETAILED DESCRIPTION

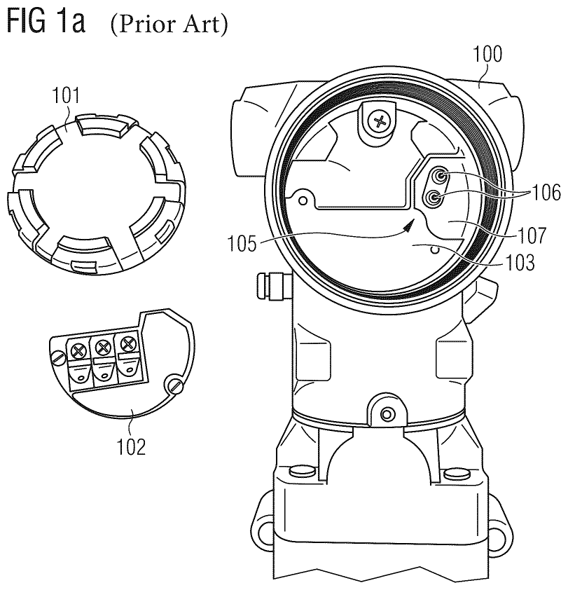

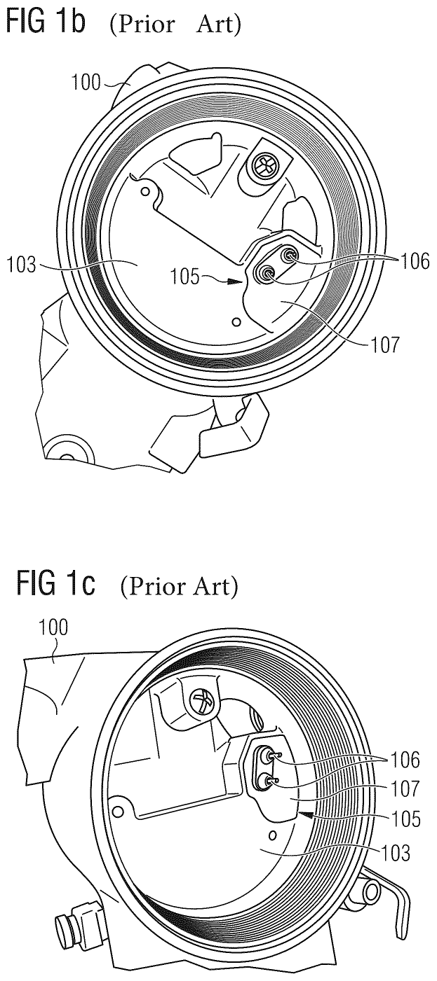

FIGS. 1a through 1c show a field device housing from Rosemount. FIG. 1a shows an opened housing 100 with a cover 101 and a connector block 102 at the left. The connector block 102 has two sockets on the rear side (concealed in the illustration) that are provided for accommodating the pin contacts 106. A chamber 103 of the housing 100 has a chamber leadthrough 105 with two pin contacts 106. The chamber leadthrough 105 together with the pin contacts 106 is completely enclosed by casting 107.

FIG. 1b shows a top view of the chamber 103 of the opened housing 100. In contrast, FIG. 1c shows an oblique view in order to more clearly depict the dimensions of the chamber 103. The chamber leadthrough 105 together with the complete casting 107, from which the pin contacts 106 protrude, is particularly clearly apparent here.

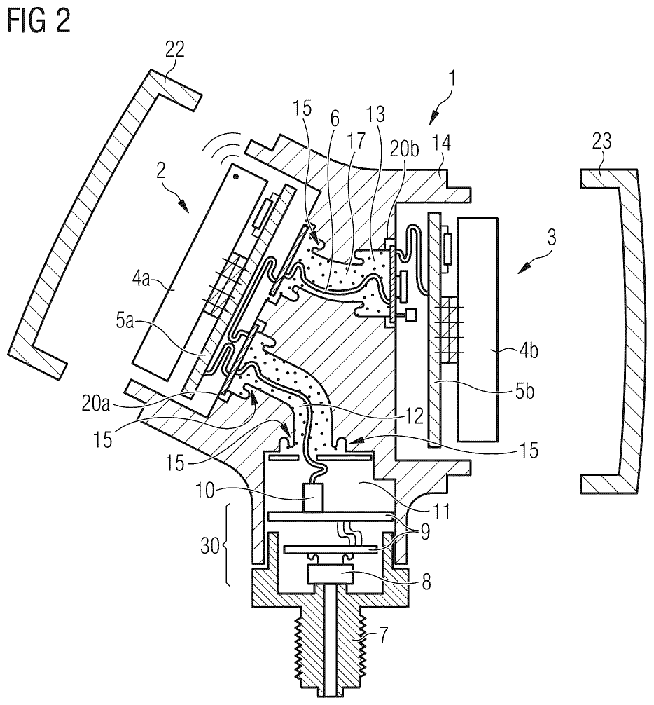

FIG. 2 shows an example of a field device assembly 1. A housing 14 has at least two chambers 2, 3, a first module 4a being arranged in the first chamber 2, and a second module 4b being arranged in the second chamber 3. The chambers 2, 3 are closed off by a cover 22, 23, respectively.

A third chamber that contains a sensor module 8 and that is closed off by a process connector 7 is arranged at a lower end of the field device assembly 1.

The housing 14 has two passages 12, 13: a passage 13 between the first chamber 4a and the second chamber 4b, and a passage 12 between the first chamber 4a and the third chamber. Between the chambers, an electrical connector 6 is guided in the passages 12, 13 for establishing an electrical connection. The electrical connector 6 includes rigid and flexible sections, the flexible sections being guided in the passages 12, 13. The rigid sections in each case are arranged at the inlets or outlets of the passages 12, 13. The shape of the inlets or outlets of the respective passage 12, 13 corresponds to the shape of the rigid section of the electrical connector 6. A high sealing effect is thus achieved without additional sealants.

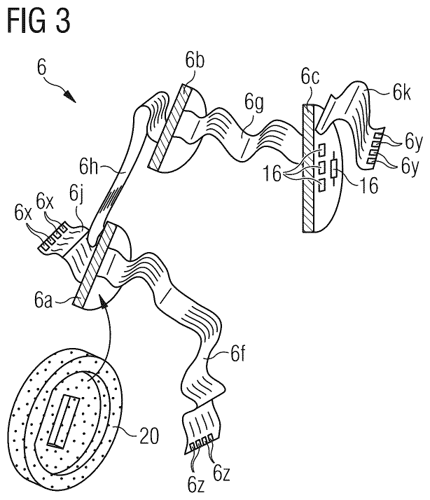

FIG. 3 shows an example of the electrical connecting element 6. The electrical connecting element 6 is a rigid circuit board, for example, which on at least one side has flexible sections 6f, 6g, 6h, 6j, 6k. The flexible sections 6g, 6h are provided between two rigid sections 6a, 6b, 6c. The open ends of the flexible sections 6f, 6j, 6k are provided with contact surfaces 6x, 6y, 6z or plugs. The rigid sections may have electrical and/or electronic components 16, for example as shown at the rigid section 6c. At least one of the rigid sections 6a, 6b, 6c may also be supported in a sealing element 20.

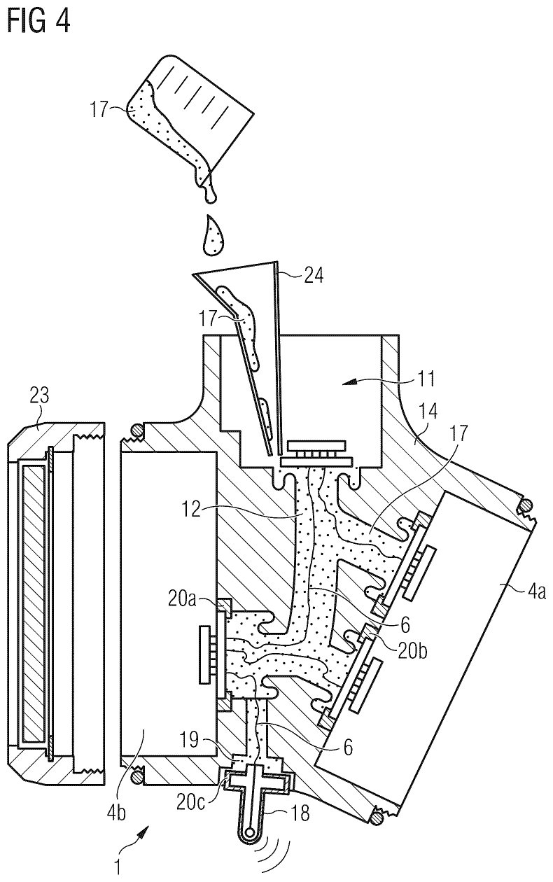

FIG. 4 shows an example of a field device assembly 1. For better understanding, the housing 14 is illustrated rotated by 180 degrees to allow a possible casting process to be depicted. The housing 14 has a central passage 12 with multiple branching limbs. Each limb leads into a respective chamber 4a, 4b, 11, 19. The chambers 4a, 4b, 11, 19 are completely covered with rigid sections of the electrical connector. Additional sealing takes place via the sealing elements 20a, 20b, 20c.

During the casting process, at the third chamber 11 a funnel 24 is placed at the opening in the passage 12, and casting compound 17 is filled in. The rigid section of the connector 6 in the chamber 11 does not completely close off the opening in the passage 12, which facilitates filling of the casting compound 17. Due to gravity the casting compound 17 flows into the chamber 19, in which a radio antenna 18 is arranged. The radio antenna 18 is electrically contactable with modules of the chambers 4a, 4b, 11 via the electrical connecting element 6. The casting compound 17 passes into each limb of the passage 12 until ultimately the passage 12 is completely filled.

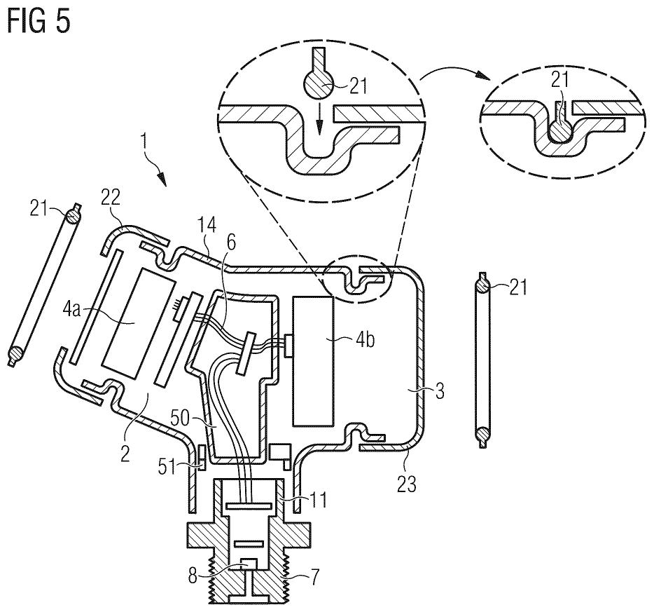

FIG. 5 shows an example of the field device assembly 1. The housing 14 is manufactured in the hydroforming process. Seals 21 are arranged between the individual housing elements. The sealing lips of the seals 21 are flush with the outer walls of the housing elements, so that this example is particularly suited for the food and beverage industry.

A block 50 which subdivides the housing 14 into the chambers as such is introducible via one of the chambers 2, 3, 11. The block 50 includes the electrical connecting element 6, via which an electrical connection is establishable between modules 4a, 4b and the sensor 8 in the chambers 2, 3, 11. The block 50 is supported and/or fixed in a bearing 51 arranged at the chamber 11. The bearing 51 may also fulfill the function of a seal, and may seal off the chamber 11 together with the sensor 8.

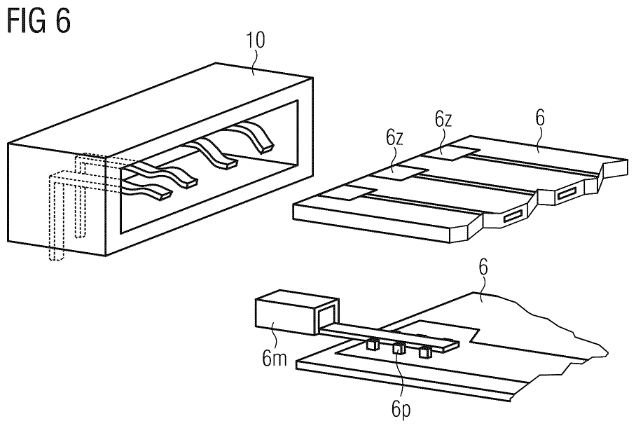

FIG. 6 schematically shows two examples of the electrical connecting element 6. Contact surfaces 6z are brought into contact with corresponding contact tongues in a connector 10. The contact surfaces are coated with tin, silver, or gold and have at least one contact point, but are preferably contacted on each side so that every two contact pairs cooperate to accommodate the countercontact between them. An alternative is use of a so-called piercing connector 6p.

Completed contact systems are provided by crimping the individual contacts through the flexible conductor tracks; i.e., they penetrate and contact the flexible conductor tracks.

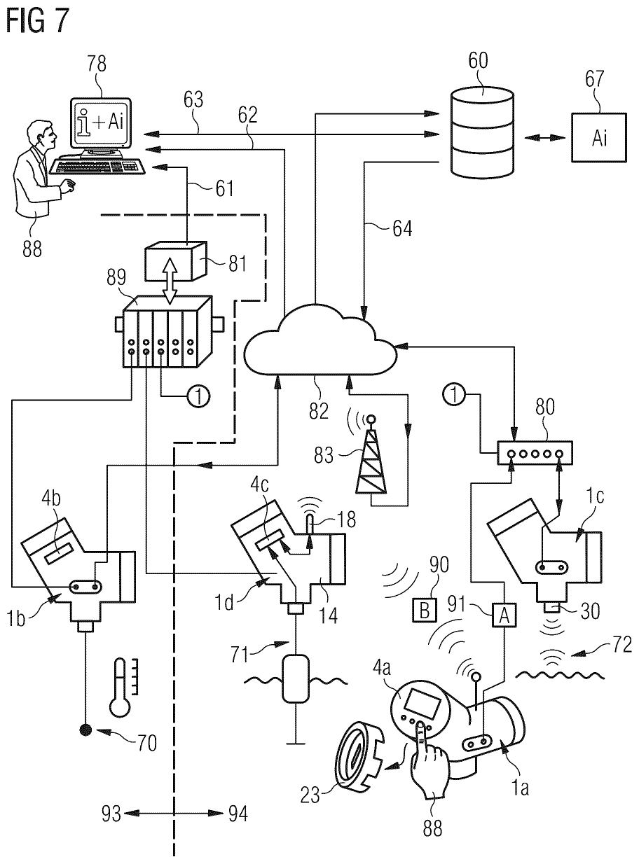

FIG. 7 shows an example of a field device assembly 1 in which the field devices 1A, 1B, 1C, 1D on the one hand are connected to a controller 89 or a programmable logic controller (PLC) 81, and on the other hand are connected to an AI system which operates using artificial intelligence methods.

At least one field device assembly 1B is present in a secure industrial zone 93, whereas other components may be installed in a normal industrial zone 94.

On the one hand, the at least one field device assembly 1B communicates via a secure connection, for example 4-20 mA or APL, with a controller 89 and a higher-level programmable logic controller (PLC) 81, which may be examined or controlled by a user 88 via a terminal 78.

Such a communication path [A] 91 is preferably wired.

On the other hand, the at least one field device assembly communicates via a further wired connection, by means of a switch 80 or wirelessly via a radio antenna 18, with a radio link site 83 and transmits data to its sensor modules 30, which evaluate pressure sensors or temperature sensors 70, or level switches 71 or level sensors 72 or other sensors, for example moisture, vibration, incident light, or internal pressure sensors, etc., which may also be integrated into the housing 14 and connected to an internal module 4 via the electrical connecting element 6.

This second connection [B] 90 is preferably wireless, but may also be wired. Via this second path, the data arrive at a cloud 82, from which the data are available to the user 88 in cockpit views in a centralized and clear manner, additionally via the second connection 62.

Via this second path, however, the data continue to a server 60 where they are preferably buffered, and then analyzed and evaluated by an AI system. Pattern recognition and deep learning methods, for example, are used here.

In a first step the data are analyzed and stored in the AI system, and in a second step the incoming data are compared to the previous data and knowledge gained therefrom, using the AI software. Analysis results from the AI system are then once again stored on the server 60, made available, and via a third connection 63 are provided to the user at a terminal 78, and supplemented with recommendations for action and warning messages.

Based on these additional data, the user may select preferences and provide input and feedback via this third path 63 to the AI system concerning which data analyses are to be prioritized.

Results and information from the AI system may also be returned 64 to the field device assembly, when this is provided beforehand in a profile for the device and enabled by the user 88.

Such results and information from the AI system may also be manually requested, viewed, and used on-site by the user via a module 4A.

The module or the field device assembly has an internal “secure area,” which is configured in particular for prioritized transmission of the data via the first connection, and an “evaluation/display area,” which via a second firmware and/or hardware structure displays or evaluates played-back information or outputs same in the form of service or alarm signals.

Such signals may pertain to increasing internal pressure or moisture or unauthorized opening of or leakage from the housing 14 in question, but may also concern analyzed irregularities, fluctuations, or reaching limits of a measured value such as pulsation, cavitation, corrosion, or vibration. In particular, for this purpose information is also graphically illustrated as a value or graphic or with reference to a temporal pattern, while in the background, data continue to be transmitted in parallel via the first connection.

For the separation between communication concerning a “secure area” and an “evaluation/display area,” i.e., the first and second connection path and the third connection path, the internal electrical connection set 6 for these areas is equipped with dedicated conductor connections in each case for the different connection paths.

A “secure industrial zone” or a “secure area” is in particular an application or an area with requirements under SIL (Safety Integrity Level) or Ex i or Ex d explosion hazard requirements.

Individual aspects from the invention may be combined with one another.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A field device assembly for process and automation technology, the assembly comprising:
a housing;
at least one first chamber;
at least one second chamber, the at least one first chamber and the at least one second chamber being arranged in the housing;
at least one first module arranged in the first chamber;
at least one second module arranged in the second chamber;
at least one passage connecting the at least one first and at least one second chamber; and
an electrical connecting element that is guided in the at least one passage, the electrical connecting element establishing an electrical connection between the first module and the second module,
wherein the electrical connecting element is made up, at least in part, of rigid sections and flexible sections, and is provided with contact surfaces or contact elements for contacting the modules.

2. The field device assembly according to claim 1, wherein the housing has a third chamber in which a sensor module is arranged.

3. The field device assembly according to claim 1, wherein the housing has at least two passages, with a first passage connecting the first chamber to the second chamber and a second passage connecting the first chamber to the third chamber.

4. The field device assembly according to claim 1, wherein the electrical connecting element establishes an electrical connection between the first module and the second module and also between the first module and the sensor module.

5. The field device assembly according to claim 1, wherein the first chamber and the second chamber are angled relative to one another.

6. The field device assembly according to claim 1, wherein at least one passage is cast with a casting material.

7. The field device assembly according to claim 1, wherein the rigid sections of the electrical connecting element are arranged in a receptacle in an entry area of the passage and at least partially cover the passage.

8. The field device assembly according to claim 1, wherein a sealing element is arranged in the entry area of the passage.

9. The field device assembly according to claim 1, wherein at least one rigid section of the electrical connecting element is pressed into an entry area or a sealing element of the passage and supported there and seals off the passage, and wherein, on an oppositely arranged opening in the passage, the at least one rigid section is at least partially covered by a further rigid section of the electrical connecting element.

10. The field device assembly according to claim 1, wherein the at least one passage has at least one undercut.

11. The field device assembly according to claim 1, wherein the rigid sections of the electrical connecting element are formed of a plurality of layers, and at least at a surface facing the modules have contact surfaces and/or plug connectors that establish the electrical connection to the modules.

12. The field device assembly according to claim 1, wherein the rigid sections of the electrical connecting element have electrical or electronic components.

13. The field device assembly according to claim 1, wherein the flexible sections of the electrical connecting element are arranged in the at least one passage.

14. The field device assembly according to claim 1, wherein the first module and/or the second module are configured such that a display module is attachable.

15. The field device assembly according to claim 1, wherein the housing is manufactured from sheet metal in a casting or hydroforming process, and wherein inner walls of the passage are unmachined.

16. The field device assembly according to claim 1, wherein the electrical connecting element is cast in a block that is centrally supported in the housing.

17. The field device assembly according to claim 1, wherein the modules are fixed and/or oriented to the block.

18. A field device assembly for process and automation technology, the assembly comprising:
a housing;
at least one first chamber and at least one second chamber arranged in the housing;
at least one first module arranged in the at least one first chamber;
at least one second module being arranged in the at least one second chamber, the first chamber and second chambers being connected via at least one passage;
an electrical connecting element that is guided in the at least one passage, the electrical connecting element being provided to establish an electrical connection between the first module and the second module,
wherein the electrical connecting element has at least different or separate conductor tracks for communication between components in a secure area and an evaluation/display area inside the field device assembly, and/or
wherein the field device assembly has a first and a second connection path, the at least one connection path being used on the 4-20 mA standard or via APL to transmit primary signals.

19. The field device assembly according to claim 18, wherein, via the communication of the internal connections regarding the “evaluation/display area” or via the second connection path, data are provided to the outside for evaluation on an AI system, or processed data and information are provided by an AI system via this second connection device for functions in the field device assembly or for display for a user.

20. A field device assembly for process and automation technology, the assembly comprising:
a housing having at least two chambers and at least one passage that connects the two chambers, a first passage connecting a first of the chambers and a second of the chambers;
at least two modules, a first of the modules being arranged in the first chamber and a second of the modules being arranged in the second chamber; and
an electrical connecting element that is guided in the at least one passage, the electrical connecting element being provided to establish an electrical connection between the first module and the second module,
wherein the electrical connecting element have at least different or separate conductor tracks for communication between components in a “secure area” and an “evaluation/display area” inside the field device assembly, and/or
wherein the field device assembly has a first and a second connection path, the at least one of the first or second connection paths being used on the 4-20 mA standard or via APL to transmit primary signals.

21. The field device assembly according to claim 20, wherein, via the communication of the internal connections regarding the evaluation/display area or via the second connection path, data are provided to the outside for evaluation on an AI system, or processed data and information are provided by an AI system via this second connection device for functions in the field device assembly or for display for a user.
